(19) United States
(12) Patent Application Publication
(10) Pub. No.: US 2024/0404954 A1
(43) Pub. Date: Dec. 5, 2024

(54) METHOD OF FORMING PACKAGE

(71) Applicant: Taiwan Semiconductor Manufacturing Company, Ltd., Hsinchu (TW)

(72) Inventors: Tsai-Tsung Tsai, Taoyuan County (TW); Ching-Hua Hsieh, Hsinchu (TW); Chih-Wei Lin, Hsinchu County (TW); Sheng-Hsiang Chiu, Tainan City (TW); Yi-Da Tsai, Chiayi Country (TW)

(73) Assignee: Taiwan Semiconductor Manufacturing Company, Ltd., Hsinchu (TW)

(21) Appl. No.: 18/800,156

(22) Filed: Aug. 12, 2024

Related U.S. Application Data
(62) Division of application No. 16/035,713, filed on Jul. 16, 2018.

(51) Int. Cl. H01L 23/538; H01L 21/56; H01L 23/00; H01L 23/31; H01L 25/065; H01L 25/18

(52) U.S. Cl. CPC H01L 23/5384; H01L 21/563; H01L 23/3185; H01L 24/11; H01L 24/81; H01L 25/0655; H01L 25/18; H01L 2224/02379; H01L 2224/12105

(57) ABSTRACT

A package and a method of manufacturing the same are provided. The package includes a first die, a second die, a third die, an encapsulant, and a redistribution layer (RDL) structure. The first die and the second die are disposed side by side. The third die is disposed on the first die and the second die to electrically connect the first die and the second die. The encapsulant laterally encapsulates the first die, the second die, and the third die and fills in a gap between the first die, the second die, and the third die. The RDL structure is disposed on the third die and the encapsulant.

### CROSS-REFERENCE TO RELATED APPLICATION

This is a divisional application of and claims the priority benefit of U.S. application Ser. No. 16/035,713, filed on Jul. 16, 2018, now pending. The entirety of the above-mentioned patent application is hereby incorporated by reference herein and made a part of this specification.

### BACKGROUND

The semiconductor industry has experienced rapid growth due to continuous improvements in the integration density of various electronic components (i.e., transistors, diodes, resistors, capacitors, etc.). For the most part, this improvement in integration density has come from continuous reductions in minimum feature size, which allows more of the smaller components to be integrated into a given area. These smaller electronic components also demand smaller packages that utilize less area than previous packages. Some smaller types of packages for semiconductor components include quad flat packages (QFPs), pin grid array (PGA) packages, ball grid array (BGA) packages, flip chips (FC), three-dimensional integrated circuits (3DICs), wafer level packages (WLPs), and package on package (POP) devices and so on.

Currently, integrated fan-out packages are becoming increasingly popular for their compactness.

### BRIEF DESCRIPTION OF THE DRAWINGS

FIG. 1A to FIG. 1G are schematic cross-sectional views illustrating a method of manufacturing a package according to some embodiments of the disclosure.

FIG. 2 is enlarged views of a portion of the structure showing in FIG. 1F.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a second feature over or on a first feature in the description that follows may include embodiments in which the second and first features are formed in direct contact, and may also include embodiments in which additional features may be formed between the second and first features, such that the second and first features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath”, “below”, “lower”, “on”, “above”, “upper” and the like, may be used herein for ease of description to describe one element or feature's relationship to another element(s) or feature(s) as illustrated in the FIG.s. The spatially relative terms are intended to encompass different orientations of the device in use or operation in addition to the orientation depicted in the FIG.s. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

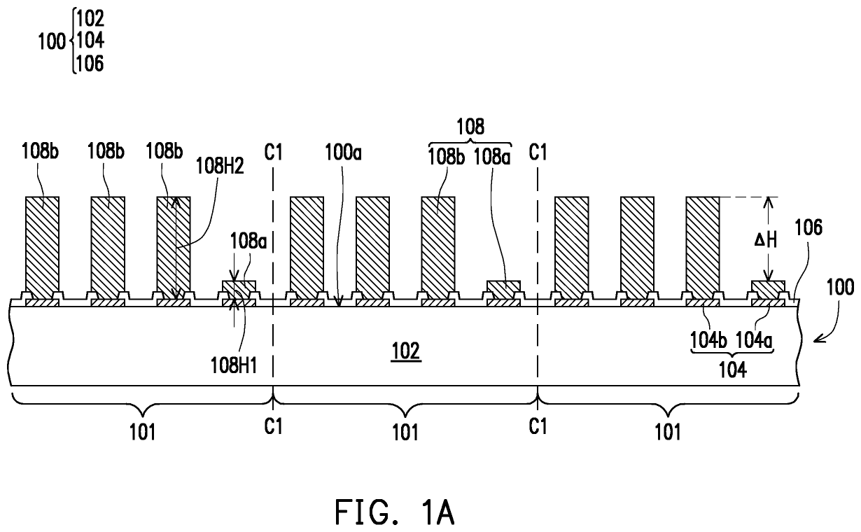

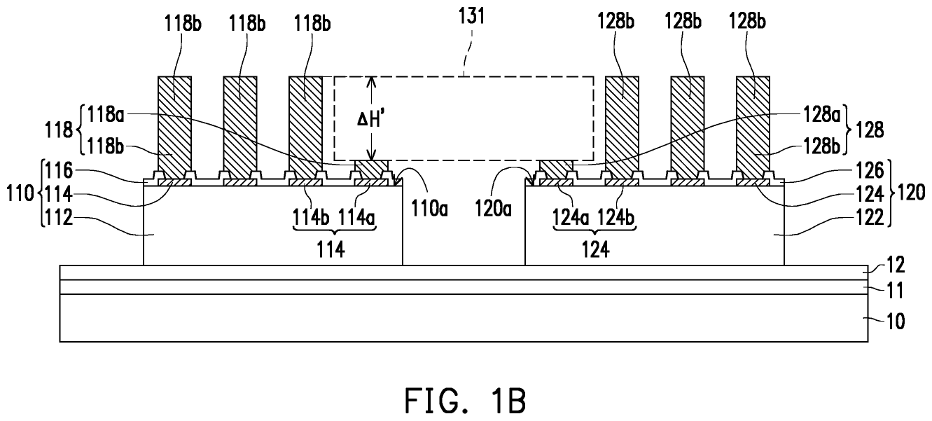

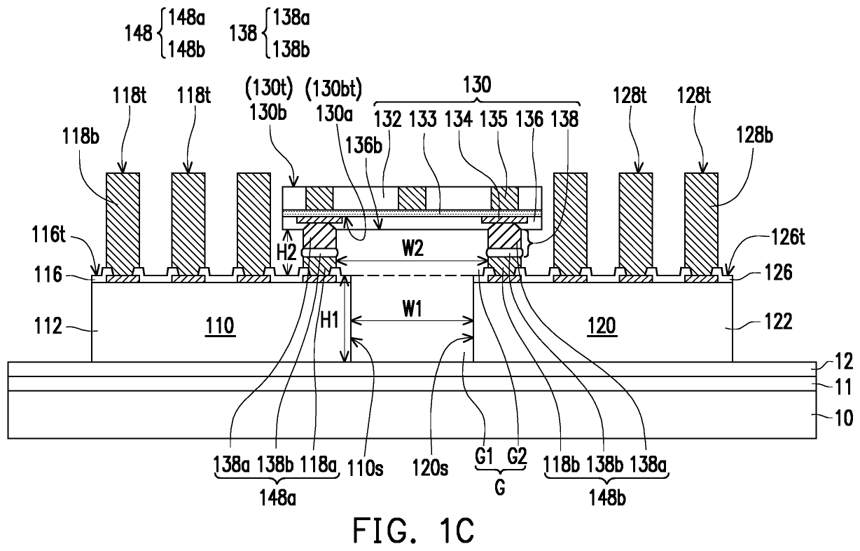

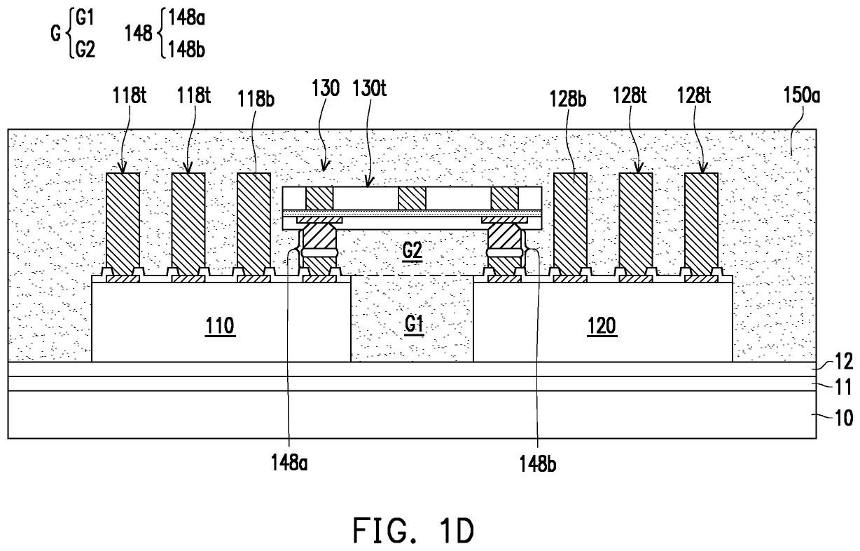

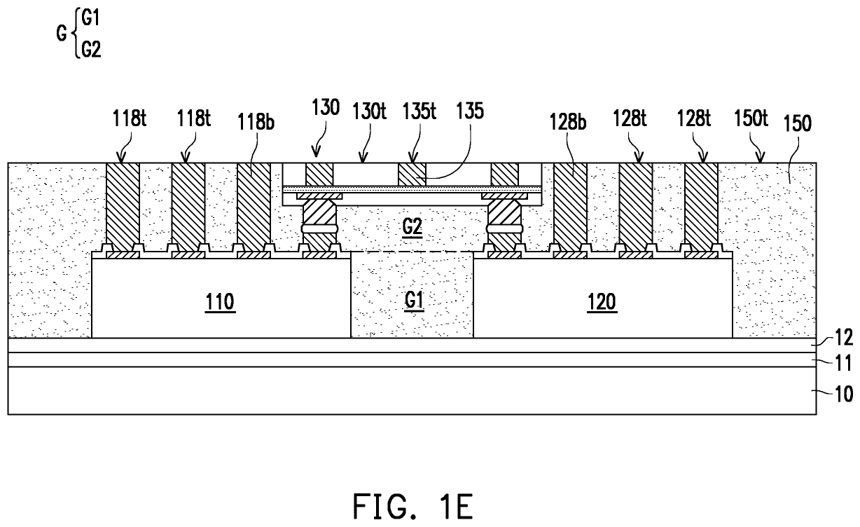

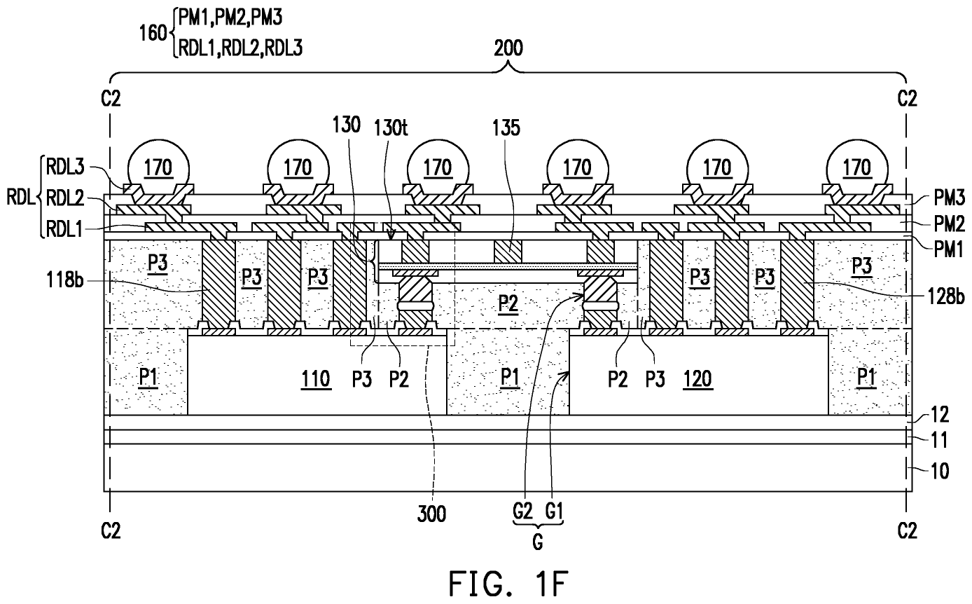

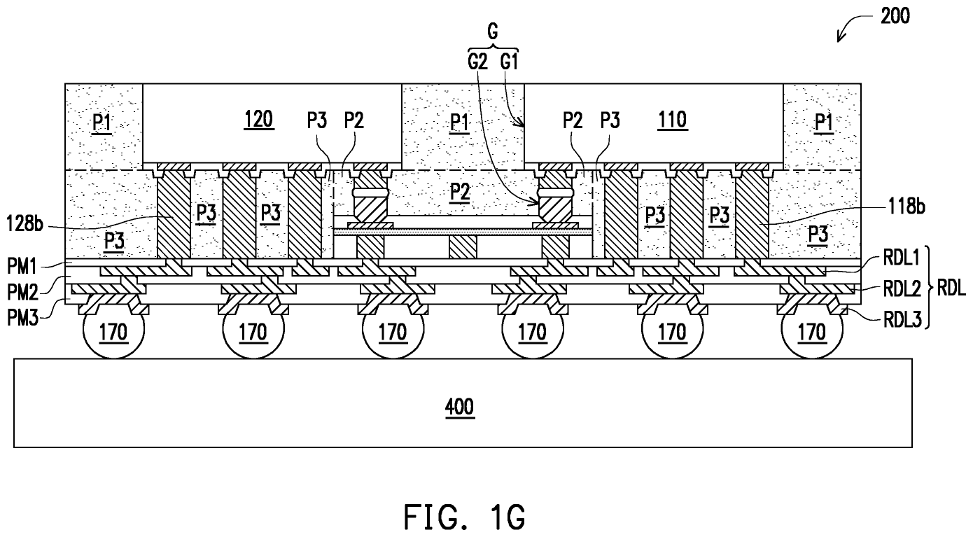

FIG. 1A to FIG. 1G are schematic cross-sectional views illustrating a method of manufacturing a package according to some embodiments of the disclosure.

Referring to FIG. 1A, a semiconductor wafer 100 is provided. The semiconductor wafer 100 includes a semiconductor substrate 102, a plurality of conductive pads 104, and a passivation layer 106. In some embodiments, the semiconductor substrate 102 may be made of silicon or other semiconductor materials. For example, the semiconductor wafer 100 may be a silicon bulk wafer. Alternatively, or additionally, the semiconductor substrate 102 may include other elementary semiconductor materials such as germanium. In some embodiments, the semiconductor substrate 102 is made of a compound semiconductor such as silicon carbide, gallium arsenic, indium arsenide or indium phosphide. In some embodiments, the semiconductor substrate 102 is made of an alloy semiconductor such as silicon germanium, silicon germanium carbide, gallium arsenic phosphide, or gallium indium phosphide. Furthermore, the semiconductor substrate 102 may be a semiconductor on insulator such as silicon on insulator (SOI) or silicon on sapphire.

The conductive pads 104 are disposed on a front side 100a of the semiconductor wafer 100. Herein, the front side 100a of the semiconductor wafer 100 is referred to as a top surface of the semiconductor substrate 102. In some embodiments, the conductive pads 104 may be a part of an interconnection structure (not shown) and electrically connected to the integrated circuit devices (not shown) formed on the semiconductor substrate 102. In some embodiments, the conductive pads 104 may be made of conductive materials with low resistivity, such as copper (Cu), aluminum (Al), Cu alloys, Al alloys, or other suitable materials. In some embodiments, the conductive pads 104 include first conductive pads 104a and second conductive pads 104b.

The passivation layer 106 is formed on the front side 100a of the semiconductor substrate 102 and covers a portion of the conductive pads 104 in some embodiments. A portion of the conductive pads 104 is exposed by the passivation layer 106 and serves as an external connection of the semiconductor wafer 100. In some embodiments, the passivation layer 106 may be a single layer or a multi-layered structure, including a silicon oxide layer, a silicon nitride layer, a silicon oxy-nitride layer, a dielectric layer formed by other suitable dielectric materials or combinations thereof.

In FIG. 1A, a plurality of conductive vias 108 are further formed on the portion of the conductive pads 104 exposed by the passivation layer 106. In detail, the conductive vias 108 includes first conductive vias 108a on and in contact with the first conductive pads 104a and second conductive vias 108b on and in contact with the second conductive pads 104b. In some embodiments, the material of the first conductive vias 108a and the second conductive vias 108b includes copper, copper alloys, or other conductive materials, and may be formed by deposition, plating, or other suitable techniques. In some embodiments, the formation of the first and second conductive vias 108a, 108b includes conformally sputtering, for example, a seed layer (not shown) on the semiconductor substrate 102, forming one or more patterned masks (not shown) having a plurality of openings corresponding to the conductive pads 104, filling in the openings with a conductive material (not shown), removing the patterned masks, and removing a portion of the seed layer uncovered by the conductive material, so as to form the first conductive vias 108a and second conductive vias 108b. In some embodiments, the first conductive vias 108a and the second conductive vias 108b are formed with different heights. In some embodiments, a height 108H1 of the first conductive vias 108a is less than a height 108H2 of the second conductive vias 108b. In some alternative embodiments, the first conductive vias 108a and the second conductive vias 108b may be formed with the same height, and the second conductive vias 108b may be further elongated by selective deposition, thereby resulting in a height difference between the second conductive vias 108b and the first conductive vias 108a. In some other alternative embodiments, rather than elongating the second conductive vias 108b, the first conductive vias 108a are shortened, for example, by performing an etching step in the presence of an auxiliary mask (not shown) that shields the second conductive vias 108b. Choice of a method to generate the height difference between the first conductive vias 108a and the second conductive vias 108b may be dictated by consideration such as overall cost of the process and design need. In any case, the method chosen to produce a difference in height between the first conductive vias 108a and the second conductive vias 108b, or even the existence of a difference in height, are not to be construed as a limitation of the present disclosure.

In the embodiments where a height difference (ΔH=|108H2−108H1|) exists between the first conductive vias 108a and the second conductive vias 108b, the height difference ΔH may be 25 μm to 325 μm. For example, the height 108H1 of the first conductive vias 108a may be 5 μm to 40 μm, and the height 108H2 of the second conductive vias 108b may be 30 μm to 330 μm. However, the disclosure is not limited. The heights 108H1 and 108H2 may be adjusted according to the design or production requirements. In some alternative embodiments, the height 108H1 of the first conductive vias 108a and the height 108H2 of the second conductive vias 108b may be the same. In some other embodiments, the first conductive vias 108a may be joint pads, and the second conductive vias 108b may be copper pillars.

In FIG. 1A, the semiconductor wafer 100 has a plurality of dies 101 formed therein, and the dies 101 are parts of the semiconductor wafer 100 defined by the cut lines C1-C1. In some embodiments, three dies 101 are shown to represent plural dies of the semiconductor wafer 100, but the number of the dies 101 in the semiconductor wafer 100 is not limited by the embodiments.

In some embodiments, one of the dies 101 may include active components (e.g., transistors or the like) and, optionally, passive components (e.g., resistors, capacitors, inductors, or the like) formed on the semiconductor substrate 102. One of the dies 101 may be or include a logic die, such as a central processing unit (CPU) die, a graphic processing unit (GPU) die, a micro control unit (MCU) die, an input-output (I/O) die, a baseband (BB) die, or an application processor (AP) die. In some embodiments, one of the dies 101 includes a memory die such as high bandwidth memory (HBM) die.

Referring to FIG. 1B, a carrier 10 is provided. The carrier 10 may be a glass carrier, a ceramic carrier, or the like. A de-bonding layer 11 is formed on the carrier 10 by, for example, a spin coating method. In some embodiments, the de-bonding layer 11 may be formed of an adhesive such as an Ultra-Violet (UV) glue, a Light-to-Heat Conversion (LTHC) glue, or the like, or other types of adhesives. The de-bonding layer 11 is decomposable under the heat of light to thereby release the carrier 10 from the overlying structures that will be formed in subsequent steps.

Still referring to FIG. 1B, a first die 110 and a second die 120 are attached side by side to the de-bonding layer 11 over the carrier 10 through an adhesive layer 12 such as a die attach film (DAF), silver paste, or the like. In some embodiments, the first die 110 and the second die 120 are form by performing a singulation step to separate the individual dies 101, for example, by cutting through the semiconductor wafer 100 along the cut lines C1-C1 (shown in FIG. 1A). The first die 110 and the second die 120 may be the same type of dies or the different types of dies.

In some embodiments, the first die 110 includes the semiconductor substrate 112, the conductive pads 114 disposed on a front side 110a of the first die 110, and the passivation layer 116 covering a portion of the conductive pads 114. Herein, the front side 110a of the first die 110 is referred to as a top surface of the semiconductor substrate 112. The conductive pads 114 includes the first conductive pad 114a adjacent to the second die 120 and the second conductive pads 114b away from the second die 120. A plurality of conductive vias 118 are further disposed on the conductive pads 114. The conductive vias 118 includes the first conductive via 118a on the first conductive pad 114a and the second conductive vias 118b on the second conductive pads 114b. In some embodiments, a height of the first conductive via 118a is less than a height of the second conductive vias 118b.

Similarly, the second die 120 includes the semiconductor substrate 122, the conductive pads 124 disposed on a front side 120a of the second die 120, and the passivation layer 126 covering a portion of the conductive pads 124. Herein, the front side 120a of the second die 120 is referred to as a top surface of the semiconductor substrate 122. A plurality of conductive vias 128 are further disposed on the conductive pads 124. The conductive pads 124 includes the first conductive pad 124a adjacent to the first die 110 and the second conductive pads 124b away from the first die 110. The conductive vias 128 includes a first conductive via 128a on the first conductive pad 124a and a second conductive vias 128b on the second conductive pads 124b. In some embodiments, a height of the first conductive via 128a is less than a height of the second conductive vias 128b.

In some embodiments, a thickness of the semiconductor substrate 112 and a thickness of the semiconductor substrate 122 may be the same or different. In some alternative embodiments, a distance between a top surface of the first conductive via 118a and a bottom surface of the semiconductor substrate 112 and a distance between a top surface of the first conductive via 128a and a bottom surface of the semiconductor substrate 122 are substantially the same. On the other hand, a distance between a top surface of the second conductive via 118b and the bottom surface of the semiconductor substrate 112 and a distance between a top surface of the second conductive via 128b and the bottom surface of the semiconductor substrate 122 are substantially the same.

After the first die 110 and the second die 120 are disposed side by side and on the adhesive layer 12, as shown in FIG. 1B, an accommodation space 131 is surrounded or built-up by the first conductive vias 118a, 128a and the second conductive vias 118b, 128b. In some embodiments, the accommodation space 131 is used to mount a third die 130 (as shown in FIG. 1C). In some alternative embodiments, a size of the accommodation space 131 may be adjusted by changing the number and/or the arrangement of the first conductive vias 118a, 128a and the second conductive vias 118b, 128b. For example, when the first conductive via 118a and/or 128a includes more than one first conductive via, the size of the accommodation space 131 will become greater to accommodate greater third die 130 or more than one third die 130. On the other hand, the size of the accommodation space 131 may be adjusted by changing a difference (ΔH′) in height between the first conductive vias 118a and/or 128a and the second conductive vias 118b and/or 128b. That is, the size of the accommodation space 131 will become greater when the difference (ΔH′) in height between the first conductive vias 118a and/or 128a and the second conductive vias 118b and/or 128b is getting greater.

Referring to FIG. 1B and FIG. 1C, the third die 130 is bonded to the first die 110 and the second die 120 in a flip-chip bonding and within the accommodation space 131. That is, the third die 130 is upside down, so that a front side 130a of the third die 130 faces toward the carrier 10. In the case, a back side 130b of the third die 130 is referred to as a top surface 130t of the third die 130, while the front side 130a of the third die 130 is referred to as a bottom surface 130bt of the third die 130.

In some embodiments, the third die 130 may be a bridge, such as a silicon bridge, providing an interconnecting structure for the first die 110 and the second dies 120 and providing shorter electrical connection path between the first die 110 and the second dies 120. In other words, in some embodiments in which the third die 130 is the bridge, the third die 130 includes interconnecting structure, and frees from active components (e.g., transistors or the like) and/or passive components (e.g., resistors, capacitors, inductors, or the like).

In some alternative embodiments, the third die 130 may include an interconnecting structure and active components (e.g., transistors or the like) and, optionally, passive components (e.g., resistors, capacitors, inductors, or the like). The third die 130, the first die 110, and the second die 120 may be the same type of dies or the different types of dies. For example, the first die 110 and the second die 120 are both HBM dies, while the third die 130 is system on chip (SoC) die. In some embodiments, the size or width of the third die 130 is substantially equal to the size or width of the first die 110 and/or second die 120, as shown in FIG. 1C. In other embodiments, the size or width of the third die 130 is greater than the size or width of the first die 110 and/or second die 120. In some alternative embodiments, the size or width of the third die 130 is less than the size or width of the first die 110 and/or second die 120 when the third die 130 is the silicon bridge.

In detail, referring to FIG. 1C, the third die 130 includes a semiconductor substrate 132, a device layer 133, a plurality of conductive pads 134, a passivation layer 136, and a plurality of connectors 138. The material and forming method of the semiconductor substrate 132, the conductive pads 134, and the passivation layer 136 are similar to the material and forming method of the semiconductor substrate 102, the conductive pads 104, and the passivation layer 106 illustrated in above embodiments. Thus, details thereof are omitted here. In some embodiments, the third die 130 further includes a plurality of through semiconductor vias (TSVs) 135. The TSVs 135 penetrate through the semiconductor substrate 132 to electrically connect to the device layer 133. Alternatively, the TSVs 135 further penetrate through the device layer 133 to electrically connect to the interconnection structure (not shown) between the device layer 133 and the conductive pads 134. In some embodiments, the TSVs 135 includes a conductive via and a diffusion barrier layer (not shown) surround the conductive via. The conductive via may include copper, copper alloys, aluminum, aluminum alloys, or combinations thereof. The diffusion barrier layer may include Ta, TaN, Ti, TiN, CoW or a combination thereof.

Referring to FIG. 1C, the device layer 133 is formed on the semiconductor substrate 132. The device layer 133 includes a wide variety of integrated circuit devices (not shown) formed on the semiconductor substrate 132. In some embodiments, the integrated circuit devices may include active devices (e.g., diodes, transistors, optoelectronic devices, or like), and/or passive devices (e.g., resistors, capacitors, inductors, or like). In some alternative embodiments, the device layer 133 may be omitted when the third die 130 is provided to be used as the bridge.

The conductive pads 134 is formed on the front side 130a of the semiconductor substrate 132. The conductive pads 134 may be a part of an interconnection structure (not shown) and electrically connected to the device layer 133 formed on the semiconductor substrate 132. The passivation layer 136 is formed on the front side 130a of the semiconductor substrate 132 and covers a portion of the conductive pads 134.

The connectors 138 are formed on the conductive pads 134 exposed by the passivation layer 136. In some embodiments, the connectors 138 are micro-bumps containing copper posts 138a and solder caps 138b, but the disclosure is not limited thereto, and other conductive structures such as solder bumps, gold bumps or metallic bumps may also be used as the connectors 138. In some alternative embodiments, the connectors 138 may be copper posts 138a without solder caps 138b. In FIG. 1C, the third die 130 is bonded to the first die 110 and the second die 120 by the connectors 138. In some embodiments, the connectors 138 of the third die 130 may be bon40ded to the first conductive vias 118a and 128a through a reflow process

In FIG. 1C, one of the connectors 138 is bonded to the first conductive via 118a formed on the first die 110 to form a bonding structure 148a, and another one of the connectors 138 is bonded to the first conductive via 128a formed on the second die 120 to form another bonding structure 148b. That is, the third die 130 traverses or extends over a gap G formed between the first die 110 and the second die 120. As shown in FIG. 1C, the gap G is surrounded or built-up by the third die 130, the first die 110 and the second die 120.

In detail, the gap G may include a first gap G1 and a second gap G2 on the first gap G1. The first gap G1 is surrounded or defined by a sidewall 110s of the first die 110 and a sidewall 120s of the second die 120 adjacent to each other, and a top surface 116t or 126t of the passivation layer 116 or 126. The second gap G2 is surrounded or defined by a bottom surface 136b of the passivation layer 136, the bonding structure 148a, 148b, and the top surface 116t or 126t of the passivation layer 116 or 126. The second gap G2 is in spatial communication with the first gap G1.

In some embodiments, a width W1 of the first gap G1 is a lateral distance between the first die 110 and the second die 120, namely, the lateral distance is between the sidewall 110s of the first die 110 and the sidewall 120s of the second die 120. A height H1 of the first gap G1 is a longitudinal distance between a bottom surface 112b of the semiconductor substrate 112 and the top surface 116t or 126t of the passivation layer 116 or 126. In some embodiments, the width W1 of the first gap G1 may be 45 μm to 1000 μm, the height H1 of the first gap G1 may be 100 μm to 600 μm, and an aspect ratio (H1/W1) of the first gap G1 may be 0.1 to 13.3.

In some embodiments, a width W2 of the second gap G2 is a lateral distance between bonding structure 148a and 148b. A height H2 of the second gap G2 is a longitudinal distance between the bottom surface 136b of the passivation layer 136 and the top surface 116t or 126t of the passivation layer 116 or 126. In some embodiments, the width W2 of the second gap G2 may be 45 μm to 20000 μm and the height H2 of the second gap G2 may be 10 μm to 80 μm.

In FIG. 1C, the top surface 130t of the third die 130 is less than top surfaces 118t and 128t of the second conductive vias 118b and 128b after mounting the third die 130 on the first die 110 and the second die 120. However, the disclosure is not limited. In some alternative embodiments, the top surface 130t of the third die 130 may be greater than or equal to the top surfaces 118t and 128t of the second conductive vias 118b and 128b after mounting the third die 130 on the first die 110 and the second die 120.

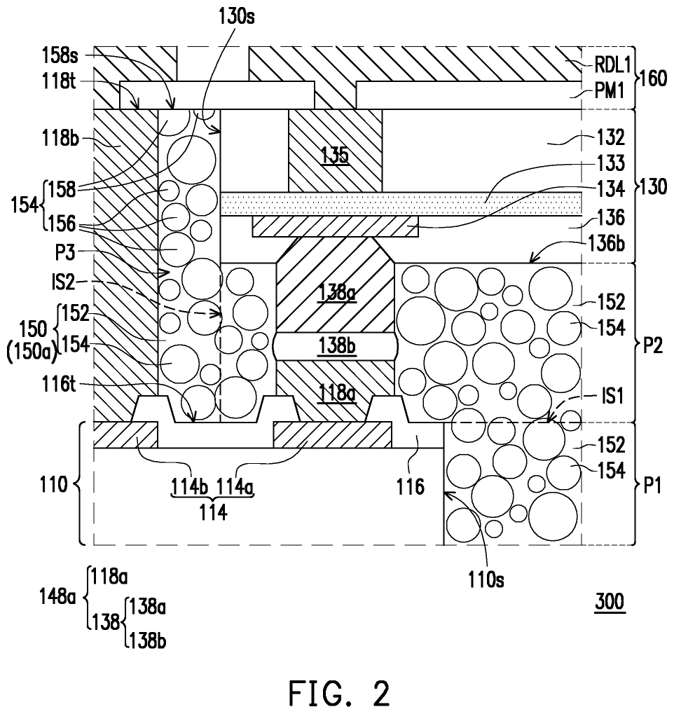

Referring to FIG. 1D, an encapsulation material 150a is formed over the carrier 10 to encapsulate the first die 110, the second die 120, the third die 130 and fill in the gap G between the first die 110, the second die 120, and the third die 130. In addition, the bonding structures 148 and the conductive vias 118 and 128 are fully covered and not revealed by the encapsulation material 150a. Further, the encapsulation material 150a is formed to cover the top surfaces 118t and 128t of the second conductive vias 118b and 128b and the top surface 130t of the third die 130. In some embodiments, the encapsulation material 150a includes a molding compound, a molding underfill, a resin (such as an epoxy resin), or a combination thereof, or the like. In some alternative embodiments, the encapsulation material 150a has a viscosity of 5000 mPa·s to 500000 mPa·s. As shown in FIG. 2, the encapsulation material 150a may include a base material 152 and a plurality of filler particles 154 in the base material 152. In some embodiments, the base material 152 may be a polymer, a resin, an epoxy, or the like; and the filler particles 154 may be dielectric particles of SiO₂, Al₂O₃, silica, or the like, and may have spherical shapes. In some alternative embodiments, the filler particles 154 may be solid or hollow. Also, the filler particles 154 may have a plurality of different diameters. In some embodiments, the filler particles 154 has a diameter of 5000 nm to 25000 nm. In some other embodiments, the filler particles 154 has an average diameter of 1000 nm to 10000 nm. The diameter of the filler particles 154 should be small enough to fill in the small gap G. In some other embodiments, a content of the filler particles 154 is about 70 wt % to about 90 wt % based on the total weight of the encapsulation material 150a.

Referring to FIG. 1D, in some embodiments, the encapsulation material 150a is formed by an immersion molding process. In detail, a mold having a cavity (not shown) is provided. The encapsulation material 150a is provided in the cavity of the mold. The structure illustrated in FIG. 1C is upside down and dipped in the encapsulation material 150a, so that the encapsulation material 150a fills in the gap G (including the first gap G1 and the second gap G2) and laterally encapsulates the first die 110, the second die 120, and the third die 130. Thereafter, a curing process is performed on the encapsulation material 150a. Unlike the conventional transfer molding process and the compression molding process, the encapsulation material 150a is ease to fill in the first gap G1 with high aspect ratio and the second gap G2 with small space in the immersion molding process. Therefore, the encapsulation material 150a is able to be distributed uniformly on the whole carrier 10 (including at the edge or the center of the carrier 10) and only few air void included in the encapsulation material 150a filled in the first gap G1 and the second gap G2. That is, the immersion molding process is suitable for high throughput due to the simplified process flow and has an advantage of decreasing process cost. Moreover, the immersion molding process is also suitable for small package form.

Referring to FIG. 1D and FIG. 1E, in some embodiments, the encapsulation material 150a may be partially removed by a planarizing process until top surfaces 135t of the TSVs 135 of the third die 130 are exposed. In some embodiments, upper portions of the second conductive vias 118b and 128b and/or an upper portion of the third die 130 may also be removed during the planarizing process. Planarization of the encapsulation material 150a may produce an encapsulant 150 located over the carrier 10 to laterally encapsulate the first die 110, the second die 120, the third die 130 and fill in the gap G between the first die 110, the second die 120, and the third die 130. In the case, the conductive vias 118 and 128 (including the first conductive vias 118a, 128a and the second conductive vias 118b, 128b) are laterally encapsulated by the encapsulant 150, as shown in FIG. 1E. Therefore, the conductive vias 118 and 128 may be referred to as through insulating vias (TIVs) 118 and 128 hereafter. The first conductive vias 118a, 128a and the second conductive vias 118b, 128b are also referred to as the first TIVs 118a, 128a and the second TIVs 118b, 128b hereafter. In some embodiments, the planarization of the encapsulation material 150a includes performing a mechanical grinding process and/or a chemical mechanical polishing (CMP) process. After the grinding process or the polishing process, the top surface 130t of the third die 130 and the top surfaces 118t and 128t of the second conductive vias 118b and 128b may be substantially coplanar with a top surface 150t of the encapsulant 150.

Referring to FIG. 1F, a redistribution layer (RDL) structure 160 is formed on the encapsulant 150 and the top surface 130t of the third die 130. The RDL structure 160 is electrically connected to the first die 110 through the second TIVs 118b and electrically connected to the second die 120 through the second TIVs 128b. In some embodiments, the first die 110 is electrically connected to the second die 120 through the second TIVs 118b, 128b and the RDL structure 160. In addition, the RDL structure 160 is electrically connected to the third die 130 through the TSVs 135. In some embodiments, the RDL structure 160 includes a plurality of polymer layers PM1, PM2, and PM3 and a plurality of redistribution layers RDL1, RDL2, and RDL3 stacked alternately. The number of the polymer layers or the redistribution layers is not limited by the disclosure.

In some embodiments, the redistribution layer RDL1 penetrates through the polymer layer PM1 to electrically connect to the second TIVs 118b, 128b and the TSVs 135 of the third die 130. The redistribution layer RDL2 penetrates through the polymer layer PM2 and is electrically connected to the redistribution layer RDL1. The redistribution layer RDL3 penetrates through the polymer layer PM3 and is electrically connected to the redistribution layer RDL2. In some embodiments, the polymer layers PM1, PM2, and PM3 include a photo-sensitive material such as polybenzoxazole (PBO), polyimide (PI), benzocyclobutene (BCB), a combination thereof or the like. In some embodiments, the redistribution layers RDL1, RDL2, and RDL3 include conductive materials. The conductive materials include metal such as copper, nickel, titanium, a combination thereof or the like, and are formed by an electroplating process. In some embodiments, the redistribution layers RDL1, RDL2, and RDL3 respectively includes a seed layer (not shown) and a metal layer formed thereon (not shown). The seed layer may be a metal seed layer such as a copper seed layer. In some embodiments, the seed layer includes a first metal layer such as a titanium layer and a second metal layer such as a copper layer over the first metal layer. The metal layer may be copper or other suitable metals. In some embodiments, the redistribution layers RDL1, RDL1, and RDL3 respectively includes a plurality of vias and a plurality of traces connected to each other. The vias penetrate through the polymer layers PM1, PM2 and PM3 and connect to the traces, and the traces are respectively located on the polymer layers PM1, PM2, and PM3, and are respectively extending on the top surfaces of the polymer layers PM1, PM2, and PM3. In some embodiments, the topmost redistribution layer RDL3 is also referred as under-ball metallurgy (UBM) layer for ball mounting.

Thereafter, a plurality of conductive terminals 170 are formed over and electrically connected to the redistribution layer RDL3 of the redistribution layer structure 160. In some embodiments, the conductive terminals 170 are made of a conductive material with low resistivity, such as Sn, Pb, Ag, Cu, Ni, Bi or an alloy thereof, and are formed by a suitable process such as evaporation, plating, ball drop, screen printing, or a ball mounting process. The conductive terminals 170 are electrically connected to the first die 110 and the second die 120 through the RDL structure 160 and the second TIVs 118b and 128b. The conductive terminals 170 are electrically connected to the third die 130 through the RDL structure 160 contacting the TSVs 135.

In FIG. 1F, after the conductive terminals 170 are formed on the redistribution layer structure 160, a singulation process is performed to dice the structure illustrated in FIG. 1F along the cut lines C2-C2 to form a plurality of semiconductor packages 200. In some embodiments, the singulation process involves performing a wafer dicing process with a rotating blade or a laser beam. In other words, the dicing or singulation process is a laser cutting process, a mechanical cutting process, or any other suitable process.

Referring to FIG. 1F and FIG. 1G, after performing the singulation process, the adhesive layer 12, the de-bonding layer 11, and the carrier 10 are detached from the semiconductor packages 200 and then removed. In some embodiments, the de-bonding layer 11 (e.g., the LTHC release layer) is irradiated with a UV laser so that the carrier 10 and the de-bonding layer 11 are easily peeled off from the semiconductor packages 200. Nevertheless, the de-bonding process is not limited thereto, and other suitable de-bonding methods may be used in some alternative embodiments.

In FIG. 1G, after the semiconductor packages 200 is released from the adhesive layer 12, the de-bonding layer 11, and the carrier 10, the semiconductor packages 200 may be mounted and bonded to a circuit carrier 400, such as a printed circuit board, a mother board, or the like.

FIG. 2 illustrates an enlarged view of region 300 in semiconductor packages 200 as shown in FIG. 1F.

Referring to FIG. 1F and FIG. 2, the encapsulant 150 may be integrally formed which means the encapsulant 150 filling in the first gap G1, extending upside to fill in the second gap G2, and continuing to laterally encapsulate the bonding structure 148 and the second TIVs 118b and 128b. In some embodiments, the encapsulant 150 includes a first portion P1, a second portion P2, and a third portion P3. Herein, the first portion P1 is defined as a region filling in the first gap G1 between the first die 110 and the second die 120 and laterally encapsulating the first die 110 and the second die 120. The second portion P2 is defined as a region filling in the second gap G2, laterally encapsulating the bonding structure 148a (including the first conductive vias 118a and the connectors 138) between the first die 110 and the third die 130, and laterally encapsulating the bonding structure 148b (including the first conductive vias 128a and the connectors 138 connecting to each other) between the second die 120 and the third die 130. The third portion P3 is defined as a region laterally encapsulating the third die 130, the second portion P2, and the second TIVs 118b and 128b. In some embodiments, the first portion P1, the second portion P2, and the third portion P3 have the same material, such as a molding compound, a molding underfill, a resin (such as an epoxy resin), or the like. Herein, the same material means the first portion P1, the second portion P2, and the third portion P3 have the material with substantially the same viscosity, the same average diameter of the filler particles 154, or the same content of the filler particles 154. In some alternative embodiments, the average diameter of the filler particles 154 filling in the gap G is less than the average diameter of the filler particles 154 distributed in other regions out of the gap G.

In FIG. 2, the encapsulant 150 may include the base material 152 and the filler particles 154 in the base material 152. In some embodiments, the base material 152 may be a polymer, a resin, an epoxy, or the like; and the filler particles 154 may be dielectric particles of SiO₂, Al₂O₃, silica, or the like. In some alternative embodiments, the filler particles 154 may be solid or hollow dielectric particles. In addition, the filler particles 154 may include a plurality of spherical particles 156 and a plurality of partial particles 158. In some embodiments, the spherical particles 156 may have a plurality of different diameters.

It should be noted that, in some embodiments, since a portion of the encapsulant 150 facing the first die 110, the second die 120, and the third die 130 is not planarized through CMP or mechanical grinding, the spherical particles 156 in contact with the illustrated the top surface 116t of the passivation layer 116, the sidewall 110s of the first die 110, the bottom surface 136b of the passivation layer 136, and the sidewall 130s of the third die 130 have spherical surfaces. In some alternative embodiments, the spherical particles 156 in contact with a top surface of the adhesive layer 12 and sidewalls of the second TIVs 118b and 128b illustrated in FIG. 1F also have spherical surfaces. As a comparison, another portion of the encapsulant 150 (e.g., the third portion P3) in contact with the polymer layer PM1 has been planarized in the step shown in FIG. 1E. Accordingly, the filler particles 154 in contact with the polymer layer PM1 are partially cut during the planarization, and hence will have substantially planar top surfaces (rather than rounded top surfaces) in contact with the polymer layer PM1. Inner spherical particles 156 not subjected to the planarization, on the other hand, remain to have the original shapes with non-planar (such as spherical) surfaces. Throughout the description, the filler particles 154 that have been polished in the planarization are referred to as partial particles 158. That is, in some embodiments, the first portion P1 and the second portion P2 are full of the spherical particles 156 and are free from the partial particles 158. In some embodiments, a surface 158s that the partial particles 158 are in contact with the RDL structure 160 and the top surfaces 118t of the second TIVs 118b are substantially coplanar.

As shown in FIG. 2, since the first portion P1, the second portion P2 and the third portion P3 are formed in the same step (e.g., the immersion molding process), a first interface IS1 is not included between the first portion P1 and the second portion P2, and a second interface IS2 is not included between the second portion P2 and the third portion P3. That is, the first portion P1 and the second portion P2 are free from an interface, and the second portion P2 and the third portion P3 are free from another interface. Herein, the first interface IS1 and the second interface IS2 is viewed as virtual interfaces (illustrated as dash lines in FIG. 2) that do not actually exist in the encapsulant 150. In FIG. 2, the first portion P1 and the second portion P2 share at least one of the spherical particles 156 (i.e., a common spherical particle), while the second portion P2 and the third portion P3 share least another one of the spherical particles 156 (i.e., another common spherical particle). In some other embodiments, the spherical particles 156, but no partial particles 158, are included at the first interface IS1 and at the second interface IS2.

In view of the foregoing, the third die is flip-chip bonded on the first die and the second die in the accommodation space resulting from the height difference between the second TIVs and the first TIVs. The encapsulant is integrally formed, so as to fill in the gap surrounded by the first die, the second die, and, the third die and laterally encapsulate the first die, the second die, and the third die in the immersion molding process. That is, the forming of the encapsulant is simple and is able to be distributed uniformly. As a result, the forming of the encapsulant (e.g., the immersion molding process) is suitable for high throughput due to the simplified process flow and has an advantage of decreasing process cost. Furthermore, the resulting structure formed by the above method is also suitable for small package form.

In accordance with some embodiments of the disclosure, a package includes a first die, a second die, a third die, an encapsulant, and a redistribution layer (RDL) structure. The first die and the second die are disposed side by side. The third die is disposed on the first die and the second die to electrically connect the first die and the second die. The encapsulant laterally encapsulates the first die, the second die, and the third die and fills in a gap between the first die, the second die, and the third die. The RDL structure is disposed on the third die and the encapsulant.

In accordance with alternative embodiments of the disclosure, a package includes a first die, a second die, a third die, an encapsulant, and a RDL structure. The first die and the second die are disposed side by side. The third die is disposed on the first die and the second die and electrically connects the first die and the second die by a plurality of firs TIVs. The encapsulant includes a first portion, a second portion, and a third portion. The first portion laterally encapsulates the first die and the second die and fills in a gap between the first die and the second die. The second portion laterally encapsulates the plurality of first TIVs disposed between the first die and the third die and disposed between the second die and the third die. The third portion laterally encapsulates the third die and the second portion. The RDL structure is disposed on the third die and the encapsulant.

In accordance with some embodiments of the disclosure, a method of manufacturing a package includes the following steps. A first die and a second die disposed side by side are provided. A third die is mounted to the first die and the second die in a flip-chip bonding. An encapsulant is formed to fill in a gap between the first die, the second die, and the third die and laterally encapsulate the first die, the second die, and the third die. A redistribution layer (RDL) structure is formed on the third die and the encapsulant.

The foregoing outlines features of several embodiments so that those skilled in the art may better understand the aspects of the disclosure. Those skilled in the art should appreciate that they may readily use the disclosure as a basis for designing or modifying other processes and structures for carrying out the same purposes and/or achieving the same advantages of the embodiments introduced herein. Those skilled in the art should also realize that such equivalent constructions do not depart from the spirit and scope of the disclosure, and that they may make various changes, substitutions, and alterations herein without departing from the spirit and scope of the disclosure.

What is claimed is:

1. A method of forming a package, comprising:
providing a first die having a first conductive via and a second conductive via higher than the first conductive via;
providing a second die having a third conductive via and a fourth conductive via higher than the third conductive via;
mounting the first die and the second die side by side over a carrier, wherein an accommodation space is surrounded by the first, second, third, and fourth conductive vias;
bonding a third die on the first die and the second die within the accommodation space;
forming an encapsulation material over the carrier to bury the first die, the second die, and the third die; and
performing a planarizing process on the encapsulation material to expose the third die, the second conductive via, and the fourth conductive via, thereby forming an encapsulant having a first surface and a second surface opposite to each other.

2. The method of claim 1, wherein after performing the planarizing process, top surfaces of the third die, the second conductive via, and the fourth conductive via are substantially level with the second surface of the encapsulant.

3. The method of claim 1, further comprising:
forming a redistribution layer (RDL) structure on a top surface of the third die and the second surface of the encapsulant;
forming a plurality of conductive terminals on the RDL structure; and
performing a singulation process to form a plurality of semiconductor packages.

4. The method of claim 3, further comprising:
releasing the plurality of semiconductor packages from the carrier to expose back surfaces of the first and second dies, so that the back surfaces of the first and second dies are substantially level with the first surface of the encapsulant; and
bonding one of the plurality of semiconductor packages over a circuit carrier through the plurality of conductive terminals.

5. The method of claim 3, wherein the encapsulant comprises:
a plurality of spherical particles; and
a plurality of partial particles contacting the RDL structure.

6. The method of claim 5, wherein one of the plurality of partial particles has a surface contacting the RDL structure is substantially level with top surfaces of the second and the fourth conductive vias.

7. The method of claim 1, wherein the third die comprises:
a substrate;
an interconnect structure over the substrate; and
a plurality of through semiconductor vias (TSVs) penetrating through the substrate to contact the interconnect structure, wherein the third die interconnects the first die and the second die by the interconnect structure.

8. The method of claim 7, wherein after performing the planarizing process, top surfaces of the plurality of TSVs are substantially level with the second surface of the encapsulant.

9. The method of claim 1, wherein a size of the accommodation space is adjusted by changing the number and/or the arrangement of the first, second, third, and fourth conductive vias.

10. A method of forming a package, comprising:
mounting a first die and a second die side by side over a carrier;
bonding a third die onto the first die and the second die through a bonding structure, so as to form a gap surrounded by the bonding structure, and the first, second, and third dies;
forming an encapsulation material over the carrier by an immersion molding process, so as to encapsulate the first die, the second die, and the third die, and fill in the gap; and
performing a planarizing process on the encapsulation material to form an encapsulant.

11. The method of claim 10, wherein the gap comprises:
a first gap laterally surrounded by a sidewall of the first die and a sidewall of the second die adjacent to each other; and
a second gap over the first gap and laterally surrounded by a first bonding structure between the first die and the third die and a second bonding structure between the second die and the third die, wherein the second gap is in spatial communication with the first gap, and the second gap has a width greater than a width of the first gap.

12. The method of claim 11, wherein the encapsulation material comprises:
a base material; and
a plurality of spherical particles distributed in the base material, wherein a portion of the plurality of spherical particles extends from the first gap to the second gap to across an interface between the first gap and the second gap.

13. The method of claim 12, wherein the first gap and the second gap share at least one of the plurality of spherical particles.

14. The method of claim 10, wherein the bonding structure comprises a solder sandwiched between two metal posts, and the solder and the metal posts are laterally encapsulated by and in physical contact with the encapsulant.

15. The method of claim 10, further comprising:
forming a redistribution layer (RDL) structure on the third die and the encapsulant;
forming a plurality of conductive terminals on the RDL structure; and
performing a singulation process to form a plurality of semiconductor packages.

16. The method of claim 15, further comprising:
releasing the plurality of semiconductor packages from the carrier to expose back surfaces of the first and second dies, so that the back surfaces of the first and second dies are substantially level with a top surface of the encapsulant away from the RDL structure; and
bonding one of the plurality of semiconductor packages over a circuit carrier through the plurality of conductive terminals.

17. A method of forming a package, comprising:
providing a first die and a second die disposed side by side;
bonding a third die to the first die and the second die in a flip-chip bonding;
forming an encapsulant to fill in a gap between the first die, the second die, and the third die and laterally encapsulate the first die, the second die, and the third die; and
forming a redistribution layer (RDL) structure on the third die and the encapsulant.

18. The method of claim 17, wherein the forming the encapsulant comprises an immersion molding process.

19. The method of claim 17, further comprising:
forming a plurality of first through insulating vias (TIVs) and a plurality of second TIVs on the first die and the second die respectively, wherein the plurality of first TIVs are laterally between the plurality of second TIVs on the first die and the plurality of second TIVs on the second die, and a height of the plurality of first TIVs is less than a height of the plurality of second TIVs.

20. The method of claim 19, wherein the forming the encapsulant comprises:
forming an encapsulation material to bury the first die, the second die, and the third die, wherein a top surface of the plurality of second TIVs is between a top surface of the encapsulation material and a top surface of the third die; and
performing a planarizing process on the encapsulation material to expose the third die and the plurality of second TIVs, thereby forming the encapsulant.
